(19) United States
(12) Patent Application Publication
(10) Pub. No.: US 2010/0143811 A1
(43) Pub. Date: Jun. 10, 2010

(54) Water Oxidation Catalyst

(76) Inventors: Robin Brimblecombe, Victoria (AU); Leone Spiccia, Victoria (AU); Charles Gerard Dismukes, Princeton, NJ (US); Gerry F. Swiegers, Victoria (AU)

Correspondence Address: MCCARTER & ENGLISH, LLP NEWARK, FOUR GATEWAY CENTER, 100 MULBERRY STREET, NEWARK, NJ, 07102, US

(21) Appl. No.: 12/532,757

(22) PCT Filed: Mar. 20, 2008
(86) PCT No.: PCT/AU08/00407

§ 371 Date: Feb. 17, 2010

Related U.S. Application Data
(60) Provisional application No. 60/896,841, filed on Mar. 23, 2007.

(51) Int. Cl. H01M 8/06; B01J 23/34; B01J 31/18; C25B 11/04; C25B 9/06; C25B 1/04; H05K 3/00; H01L 21/02

(52) U.S. Cl. 429/422; 502/324; 502/152; 502/155; 204/290.01; 204/290.03; 204/242; 205/340; 29/829; 438/49; 257/E21.002

(57) ABSTRACT

A catalyst for the photo-electrolysis of water molecules, the catalyst including catalytic groups comprising tetra-manganese-oxo clusters. A plurality of the catalytic groups are supported on a conductive support substrate capable of incorporating water molecules. At least some of the catalytic groups, supported by the support substrate, are able to catalytically interact with water molecules incorporated into the support substrate. The catalyst can be used as part of photo-electrochemical cell for the generation of electrical energy.

### FIELD OF THE INVENTION

The present invention relates to manganese-oxo clusters as catalysts for the photo-electrolysis of water.

### BACKGROUND

Hydrogen (H₂) has long been considered an ideal fuel for the future. When burned in the presence of oxygen (O₂), hydrogen produces water (H₂O) as the only waste product. It therefore offers a clean, non-polluting alternative to fossil fuels.

Hydrogen has the added advantage that its reaction with oxygen may be made to take place in a solid-state device known as a fuel cell, which harnesses the resulting energy not as heat or pressure, but as an electrical current. Fuel cells offer greater inherent energetic efficiency than simple combustion of the type employed in, for example, internal combustion engines.

Because of these factors and politico-economic imperatives, development of a so-called “Hydrogen Economy” to replace the existing fossil fuel economy today forms a strategic goal of several nations, including the United States.

A convenient source of hydrogen is the solar-powered splitting of water into hydrogen (H₂) and oxygen (O₂), as depicted in equation (1).

2H₂O→O₂+2H₂ ΔH°=286 kJ/mol (1)

In an electrochemical half-cell, the water-splitting reaction comprises two half-reactions:

2H₂O→O₂+4H⁺+4 e⁻ E^{0′}=0.82 V at pH 7 (2)

2H⁺+2 e⁻→H₂ (3)

Hydrogen made from water using sunlight prospectively offers an abundant, renewable, clean energy source. However, no practical and economic catalytic system exists to facilitate this reaction. The potential of solar-produced hydrogen has, consequently, never been realized.

Photo-electrochemical (PEC) cells use light energy to drive a redox reaction. Like a normal electrochemical cell they contain a cathode and an anode separated by electrolyte containing reactants that are oxidized or reduced at the respective electrodes. In photo-electrochemical cells at least one of the half reactions is driven by solar energy; that is, sunlight is converted into chemical energy. A common example of this is the use of a photo-catalyst such as TiO₂ or WO₃ to oxidize water, with the released electrons used to reduce protons at the counter electrode. Thus, energy from the sun is converted into chemical energy in the form of the redox couple O₂ and H₂. Unfortunately TiO₂ has a relatively large band-gap of 3 to 3.2 eV, limiting its energy absorption to the ultra-violet (UV) range of the spectrum, which comprises only 4% of the solar energy. This is a major limiting factor in the efficiency of current photo-electrochemical cells.

More efficient solar powered hydrogen production can be achieved by tandem cell arrangements, which utilize photo-voltaic cells in tandem with an electrolyser, yielding hydrogen generating efficiencies of up to 12 to 20%. However these high efficiency cells typically use single crystal silicon photovoltaic technology, which, in conjunction with the electrolyser, are expensive to produce.

The light absorbing efficiency of TiO₂, (and other semiconductors), can be improved by applying a layer of a photo-active dye with improved visible light absorption properties. For example, many ruthenium(II) complexes of diimine ligands, such as the large family of bipyridines, have strong absorption maxima in the visible spectrum. Dye binding is enhanced by tethering carboxylate groups to the dyes; carboxylate groups are known to bind strongly to the semiconductor surface. Absorption of solar radiation by these dyes promotes an electron from the ruthenium(II) centre into a conduction state, allowing it to be injected into the conduction band of the semiconductor. For bipyridine ruthenium complexes, absorption of light at the ruthenium centre induces a so-called “Metal-to-Ligand-Charge-Transfer” (MLCT) transition which injects an electron into one of the coordinated pyridine rings. Through the appropriate choice of ligands, dye complexes can be designed which facilitate the transfer of the excited electron into the pyridine rings that are attached directly to the semiconductor surface (i.e., the lowest excited state corresponds to one involving promotion of electrons into the carboxylate-bearing pyridyls). Electrons promoted into higher energy states either tunnel into the semiconductor or are transported into this layer via the linking pyridine-carboxylate linker. This “sensitizing” of the semiconductor facilitates access to the visible region solar spectrum which makes up the majority of energy available in the solar radiation.

In a dye sensitized photo-voltaic cell of the type depicted in FIG. 1, the excitation of an electron into the conduction band of the semiconductor creates a potential between the two electrodes of the cell, facilitating the flow of electrons from the semiconductor electrode to a counter electrode via an external circuit (e.g. Pt). As the electron flows through this external circuit some of the potential energy can be utilised to do work. At the counter electrode the electron is used to reduce a redox active species in the solution. This reduced species is then able to diffuse in solution to the dye sensitised semiconductor where it reduces the oxidised dye completing the circuit. The most commonly used redox couple in dye sensitised solar cells is 3I⁻/I₃⁻.

Unfortunately the ruthenium(II) dyes and other photoactive dyes such as porphyrins, do not efficiently oxidize water. In addition, the oxidation of water can produce highly reactive intermediates which typically destroy the photoactive dye. Thus the application of dye sensitised semiconductor for the photo-oxidation of water has achieved little success.

The only catalyst known to be capable of sustainably photo-oxidizing water using visible light is the naturally occurring Water-Oxidizing Complex (WOC) of Photo-system II (PSII), which is found in various photosynthetic organisms in nature. The PSII-WOC catalyst achieves this feat by converting an excited state of chlorophyll (P680*) into a cation radical by charge separation that is then used to extract electrons from an inorganic core. The composition of the catalytic core of the PSII-WOC has been deduced from crystallographic, spectroscopic and physicochemical studies. It consists of a Mn₄Ca₁Oₓ cluster bridged by oxygen atoms derived from water molecules. This structure is highly conserved, being found in essentially an identical state in numerous photosynthetic organisms. Although the exact mechanism by which the PSII-WOC carries out water oxidation is still being debated, a single-crystal X-ray diffraction study of a cyanobacterial enzyme has indicated the presence of a so-called “cubane”-like Mn₃CaO₄ core, which is oxo-bridged to a fourth Mn atom. FIG. 2A depicts, in schematic form, the “cubane”-like structure of this species.

One group of PSII-WOC models are described in U.S. Pat. No. 6,316,653 (US'653) and U.S. Pat. No. 6,803,474 (US'474). These patents disclose a class of tetramanganese-oxo cubane molecules that act as homogeneous catalysts in open solution. The tetramanganese-oxo cubane molecules display structures remarkably similar to that of the active site in PSII-WOC.

In the cubane structures described in US'653 and US'474, the phosphinate ligands bridge pairs of Mn atoms, one to each of the six faces of a cube as depicted in FIG. 2B. The cubane core is surrounded by twelve hydrophobic phenyl rings that pack together, contributing to the driving force needed to hold together this otherwise unstable core. The bidentate phosphinates are essential to forming the cubical Mn₄O₆⁶⁺ core, which has unusually long Mn—O bonds that are weaker than in other Mn-oxo complexes and consequently more reactive.

The cubane has been shown by mass spectrometric analysis to be able to release molecular oxygen in the gas phase¹. Light excitation of the cubane causes photo-dissociation of a phosphinate ligand facilitating the release of two core oxygen atoms as O₂. Ultra-violet excitation achieves the release of dioxygen with 60 to 100% quantum yield in the gas phase (depending upon the phosphinate derivative). The sole other photo-chemical product is the remaining “butterfly” complex, [Mn₄O₂(Ph₂PO₂)₅]⁺ which comprises all of the remaining elements of the cubane.

A schematic of the photo-electrolysis of water is shown in FIG. 3. The overall gas phase reaction, shown in equation (4), is predicted to be favourable (ΔH°=±25 kJ/mol) on the basis of experimental bond enthalpies.

[Mn₄O₄(Ph₂PO₂)₆]→O₂+Ph₂PO₂⁻+[Mn₄O₂(Ph₂PO₂)₅]⁺ (4)

The cubane has been shown to be capable of releasing two water molecules by proton-coupled electron transfer (PCET) of two of the core oxygen atoms². Thus it is proposed that once the cubane has released O₂ it should be able to bind two water molecules and oxidize them to release the protons and incorporate the oxygen atoms into the core restoring the cubane and facilitating the cyclic oxidation of water and release of O₂. The water oxidation shown in FIG. 3 represents one catalytic cycle.

The cubane model complexes described in US'653 and US'474 are exceptionally strong oxidizing agents, with the core oxygen atoms capable of oxygenation reactions and H atom abstraction reactions. However, it has not been possible to investigate the manganese-oxo cubanes as sustainable catalysts for oxidizing water because of their insolubility in water. This insolubility arises from the hydrophobic outer shell formed by the twelve phenyl rings of the phosphinate ligands. In fact, the release of molecular oxygen by light excitation has not been observed in any condensed phases (i.e. the solid or liquid phase). Moreover, it is not clear that the calculated energy barrier for the reaction in equation (4) can be overcome in homogeneous solutions containing water. Overcoming this energy barrier depends, effectively, on disassembly of at least one phosphinate ligand in the complex when illuminated by light, which is unlikely to be favoured in aqueous solution.

### SUMMARY OF THE INVENTION

According to a first aspect of the invention there is provided a catalyst for the photo-electrolysis of water molecules, the catalyst including:
catalytic groups comprising tetra-manganese-oxo clusters;
a conductive support substrate supporting a plurality of the catalytic groups and capable of incorporating water molecules;
wherein, at least some of the catalytic groups supported by the support substrate are able to catalytically interact with water molecules incorporated into the support substrate.

During at least a part of the catalytic cycle it is believed that at least some of the catalytic groups have the formula:

[Mn₄O₄L₆]

where Mn₄O₄ is a manganese-oxo cubane core and L is a ligand stabilising the core.

It has been found that, in one embodiment, self-assembled tetra-manganese-oxo cubanes become highly active water oxidation catalysts when absorbed within a suitable polymer membrane that is immersed in an aqueous medium, illuminated with light and placed in contact with a suitable electrolysis cell. Such hybrid homogeneous-heterogeneous catalysts are active as thin layers in single layer arrangements and are incorporable into multi-layer arrangements.

“Catalytic groups” include catalytic molecules or moieties that are able to catalyse the oxidation of water by catalytically interacting with water molecules. By “catalytically interact” it is meant that the oxidation of at least some of the water molecules that contact the catalytic groups is catalysed by the catalytic groups.

The support substrate is conductive to electrons so that when an electric potential difference is present across separate points on the support substrate, the mobile charges within the support substrate are forced to move, and an electric current is generated between those points. In one embodiment, the support substrate is rendered conductive by applying a thin layer of the support substrate onto a conductive material. Suitable conductive materials include glassy carbon, platinum fluoride doped tin oxide (FTO) or ((F)SnO₂) coated glass and indium tin oxide (ITO) coated glass, and multilayer structures having nano-structured semiconductor films coated onto the conductive substrates. Other means of causing the support substrate to be conductive are within the scope of the invention. For example, in one embodiment, the support substrate contacts a sensitised semiconductor.

Preferably, the support substrate has hydrophobic regions and hydrophilic regions. While not wishing to be limited by theory, it is thought that at least some of the catalytic groups can be supported in the hydrophobic regions of the support substrate and once supported are able to catalytically interact with water molecules in the hydrophilic regions. Effectively, the support substrate is thought to act as an interface between water molecules and the hydrophobic catalytic groups which are otherwise insoluble in aqueous solution.

In one embodiment, the hydrophobic regions are formed by a hydrophobic polymeric backbone and the hydrophilic regions are regions of ionisable functional groups, preferably on the polymer backbone. Preferably the ionisable functional groups are sulphonate groups (—SO₃H) that lose a proton to form negatively charged functional groups. However, alternatively, the ionisable functional groups can form positively charged functional groups if preferred.

The support substrate can be a sulphonated fluoro-polymer (sold under the trade mark of Nafion). The hydrophobic CF₂CF(CF₃)O— polymer backbone of Nafion forms a hydrophobic solid that is penetrated by aqueous channels lined with the hydrophilic ionisable sulfonic acid groups, Investigations into the sub-structure of Nafion coatings on solid surfaces have revealed that the polymer layers contains these hydrophilic channels throughout the otherwise hydrophobic regions of the membrane. These channels allow the diffusion of small molecules such as water.

Other support substrates that could be used include, for example per-fluorinated sulfonic acid polymer cation-exchange membranes such as F-14100, F-930 and F-950, the GEFC perfluorinated proton exchange membranes, nanostructured films formed by metal oxide nanoparticles suitably decorated with organic acids including perfluorinated sulphonic acids, nanostructured films formed by the hydrolysis of alkoxysilanes suitably decorated with organic acids including perfluorinated sulphonic acids. Also within the scope are heterogeneous-homogeneous colloidal systems, two-phase mixtures (stabilised and unstabilised with surfactant), conducting polymers, surface-modified silica and titania.

The ligands surrounding the cubane core can be phosphinate molecules or groups. Other ligands which are able to replace all or some of the phosphinate molecules by coordination to the core and yet are photo-dissociable are within the scope of the invention. For example, the families of chelating molecules including carboxylate, β-diketones or sulphonates and phosphate esters. Effectively di-oxo ligands of various types can be used incorporating C═O, N═O, P═O, As═O, Si═O, as well as various combinations of ligands incorporating these groups.

Upon photo-dissociation of a ligand from a catalytic group, intermediate catalytic groups are formed. These intermediates are thought to include the positively charged cubane “butterfly” complex shown in FIG. 3 and the negatively charged ligand groups, shown in FIG. 4. While not wishing to be bound by theory, it is thought that the ionisable functional groups of the support substrate contribute to the stabilisation of at least one of these intermediate catalytic groups. For example, when the intermediate catalytic group includes a positively charged manganese atom (as in the butterfly complex), the positive charge may be stabilised by negative charges provided by the ionisable groups upon ionisation. In one embodiment, sulphonate groups are thought to stabilise the positive charges on the manganese atoms. When the intermediate catalytic group is an ionised photo-dissociated ligand, such as a negatively charged phosphinate ligand, the ligand is thought to be stabilised by donation of a proton from the ionisable functional groups of the support substrate.

Any means of contacting the catalyst with water is within the scope of the invention. In one embodiment, the catalyst is immersed in a solution containing water molecules. The solution can be an aqueous solution containing electrolyte. In one embodiment about 0.1 M electrolyte is sufficient.

The catalytic groups are believed to have a tendency to decompose in aqueous solution. For example, experiments in free solutions of CH₃CN have shown that in greater then 10% water (v/v) dissolved cubane clusters breaks down in a matter of minutes. While not wishing to be bound by theory, it is thought that when one ligand from a catalytic group photo-dissociates, the support substrate can act to stabilise the binding of the other ligands (in the same catalytic group), in order to reduce the tendency of the catalytic group to destabilise. Effectively, the immobilization of the catalytic groups in the hydrophobic regions of the support is thought to trap any of further dislodged ligands in close proximity to the core, thereby facilitating rapid rebinding of that ligand. The support therefore reduces degradation of the catalytic groups compared to the degradation observed in bulk aqueous solution.

The catalyst is thought to function according to the first two steps of the overall proposed cycle:
(i) [Mn₄O₄(L)₆]⁺→O₂+L⁻+[Mn₄O₂(L)₅]²⁺
(ii) [Mn₄O₂L₅]²⁺+L⁻+2H₂O (4H⁺+4 e⁻)->[Mn₄O₄L₆]⁺
(iii) 2H⁺+2 e⁻→H₂

Preferably the catalyst is operable over at least 1,000 cycles. More preferably, the catalyst is operable over at least 100,000 cycles. In one example of the invention, a half-cell coated with the catalyst has been operated for 7 hours which is equivalent to more than 150,000 catalytic cycles.

In one embodiment, the catalyst of the invention is formed on an electrode substrate to provide a photo-anode. The electrode substrate can be any suitable substrate, for example, glass. As mentioned above, the glass could be coated with, for example, indium tin oxide to render the support substrate conductive. In some embodiments there are multiple layers intermediate the electrode substrate and the catalyst. These layers can replace the conductive material (e.g. indium tin oxide) applied to the electrode substrate. The layers can include a semiconductor and a chemical relay system material.

The incorporation of photo-electrochemical relay system into the photo-anode improves the overall efficiency of the catalysis of water oxidation. The chemical relay system is a photo-electrochemical relay such as a dye that absorbs light and facilitates electron transfer. A thin layer of the catalyst can be in contact with the chemical relay system. The chemical relay includes polymers possessing cation exchange groups (e.g. sulfonates) that facilitate proton exchange with water and photo-active dyes such as ruthenium N-donor dyes that absorb in regions of the electromagnetic spectrum that are not absorbed by the catalytic clusters. The ruthenium N-donor dyes absorb visible light and then electrochemically oxidize the catalytic groups. This enhances the efficiency with which light in the visible region is converted into chemical energy overall, since the catalytic groups typically do not absorb visible light strongly.

The photo-anode of the invention can be used in a photo-electrochemical cell for the electrolysis of water. The cell can comprise a chamber capable of containing an aqueous electrolyte. The chamber can be bounded by walls so as to contain the aqueous electrolyte within it, or open to allow the aqueous electrolyte to flow through it. The photo-electrochemical cell includes the photo-anode in combination with a cathode, both of which are able to contact the aqueous electrolyte when it is present. When the cell is used, the photo-anode is electrically connected to the said cathode in order to complete the electrical circuit.

The photo-electrochemical cell can be used in a method of generating hydrogen and oxygen. Effectively, the cell is exposed to light radiation in order to activate the catalytic groups. When the cell is absent a photo-electrochemical relay system, an electric potential is applied to encourage the regeneration of the catalytic groups once they have undertaken one catalytic cycle. The cell is capable of producing hydrogen and oxygen gases which can be collected or immediately used in a further application as desired.

Alternatively, the photo-electrochemical cell can be used in a method of generating electricity (i.e. an electric current). Where a chemical relay system is present in the photoanode, to generate electricity all that is required is exposure of the cell to light radiation such as sunlight.

Optionally, the hydrogen and oxygen generated by the photo-electrochemical cell described above can be passed into a fuel cell for the generation of electrical energy.

In some embodiment, a plurality of photo-electrochemical cells are arranged in a series.

The invention also provides a method for preparing a photo-electrochemical cell for use in the photo-electrolysis of water, the method including the steps of:
(i) providing a conductive support substrate capable of incorporating water molecules;
(ii) allowing catalytic groups comprising tetra manganese-oxo clusters to self-assemble on the support substrate so that at least some of the catalytic groups are able to catalytically interact with the water molecules;
(iii) coating the support substrate having the catalytic groups assembled therein with onto an electrode substrate to provide a photo-anode;
(iv) providing a cathode and forming an electrical connection between the photo-anode and the cathode;
(v) providing an aqueous electrolyte between the photo-anode and the cathode to provide a photo-electrochemical cell.

According to yet a further aspect of the invention there is provided a method for preparing a photo-electrochemical cell for the catalysis of water, the method including the steps of:
(i) providing a semiconductor layer;
(ii) coating a layer comprising a photo-electrochemical relay system onto the semi-conductor layer;
(iii) coating a layer of a conductive support substrate capable of incorporating water molecules onto the semiconductor layer having the chemical relay system thereon;
(iv) allowing catalytic groups comprising tetra-manganese-oxo clusters to self-assemble on the support substrate so that at least some of the catalytic groups are able to catalytically interact with the water molecules thereby forming a photo-anode;
(v) providing a cathode and forming an electrical connection between the photo-anode and the cathode;
(vi) providing an aqueous electrolyte between the photo-anode and the cathode to provide a photo-electrochemical cell.

The active catalyst can be formed inside the channels of the support substrate by self-assembly, starting from simpler precursors known to form the catalytic groups in situ. This alternative approach for synthesis involves self-assembly whereby the appropriate phosphonic acid and manganese precursors are added to the support substrate and self-assemble in situ within or on the support.

In one form, the method further includes the step of adding species that form the catalytic groups in situ to the aqueous electrolyte. For example, manganese ions can be added to the electrolyte. The addition of manganese ions provides an excess of the chemical species necessary for forming the manganese-oxo clusters and this can allow for the rapid reformation of the catalyst should it degrade (i.e. fall apart) during a catalytic cycle.

### BRIEF DESCRIPTION OF THE FIGURES

Preferred embodiments of the invention will now be described with reference to the following drawings, which are intended to be exemplary only, and in which:

FIG. 1: is a schematic representation of a dye-sensitized titanium dioxide photo-voltaic cell (a Graetzel cell).

FIG. 2: (A) is a schematic of the coordination of PSII-WOC; its protein ligands and other important residues. Residues in D1, D2 and CP43 subunits are shown, while X₁₁, X₁₂ and X₂ denote non-protein ligands, possibly substrate water binding positions or bicarbonate site.
(B) is a schematic of the cubane core Mn₄O₄(L) of U.S. Pat. No. 6,316,653 and U.S. Pat. No. 6,803,474 (left). (For clarity only one of the six ligands on the cubane has been drawn, with the other five represented by simple chelating bonds). L₁ diphenyl phosphinic acid (R═H), L₂ bis-methoxy diphenyl phosphinic acid (R═OCH₃). The right-hand structure is an X-Ray Diffraction-derived depiction of synthetic molecule (Ph₂PO₂)₆Mn₄O₄ and its central Mn₄O₄⁶⁺ cubane core.

FIG. 3: Schematic of a proposed mechanism of water oxidation by a tetra-manganese-oxo cubane catalytic group.

FIG. 4: (A) Schematic of the molecular structure of Nafion.
(B) Schematic of the cubane catalytic groups incorporated into the support substrate of the present invention. Cationic L₆Mn₄O₄⁺ cubane molecules are shown as having been drawn into the aqueous Nafion channels by ion exchange, displacing protons and remaining loosely associated with sulfonate anions.
(C) Proposed catalytic photo-electrolysis cycle.

FIG. 5: is a cyclic voltammetry obtained at 22° C. for oxidation of 2 in Nafion (—) and Nafion ( - - - - ) on a 3 mm diameter glassy carbon disc electrode in H₂O (0.1 M Na₂SO₄), 50 mV/s

FIG. 6: is a plot of photo-current from controlled potential electrolysis at 1 V (vs Ag/AgCl) obtained at 22° C. for 2⁺ in Nafion on a 1 mm diameter platinum electrode in H₂O (0.1 M Na₂SO₄) against monochromatic excitation wavelengths at 25 nm intervals.

FIG. 7: is a plot of photo-current from controlled potential electrolysis at 1 V (vs Ag/AgCl) obtained at 22° C. for 2⁺ in Nafion in CH₃CN (0.1 M ^{t}Bu₄NPF₆) with increasing percentage (v/v) of water in working solution. The insert shows a controlled potential electrolysis at 1 V (vs Ag/AgCl) obtained at 22° C. for 2⁺ in Nafion in CH₃CN (0.1M Bu₄NPF₆) ( - - - - ) and in CH₃CN (0.1M Bu₄NPF₆) with 10% (v/v) water (—) 3 mm diameter glassy carbon disc electrode.

FIG. 8: MIMS trace of a solution of 50% H₂¹⁸O with 0.1 M Na₂SO₄ exposed to a cubane doped Nafion electrode and light for one hour and passed through a MIMS tracing amu 36 (the trace with dashed lines show average partial pressure). The grey line is the same solution exposed to a Nafion only coated electrode with light for one hour.

FIG. 9: is a plot of the photo-current from controlled potential electrolysis at 1 V (vs Ag/AgCl) obtained at 22° C. for 2⁺ in Nafion in H₂O (0.1 M Na₂SO₄) at a range of pH conditions.

FIG. 10: is a controlled potential electrolysis at 1 V (vs Ag/AgCl) obtained at 22° C. for 2⁺ in Nafion on a 3 mm diameter glassy carbon disc electrode in H₂O (0.1 M Na₂SO₄), exposed to white light, of intensity approximately equivalent to standard simulated sunlight AM 1.5, every 20 seconds.

FIG. 11 is a schematic depiction of the cross-sectional structure of the photo-anode according to a preferred embodiment of the present invention (left) relative to the comparable structure of the natural, photosynthetic water-oxidizing centre in Photo-system II,

FIG. 12: is a cyclic voltammogram obtained for 2⁺ doped in Nafion (top left) and Ru(bipy)₃²⁺ (top right) and both 2⁺ and [Ru(bipy)₃]²⁺ (bottom) doped in Nation® on a glassy carbon electrode, in H₂O (0.1 M Na₂SO₄), 10 mV/s, vs Ag/AgCl.

FIG. 13: is a controlled potential electrolysis at 1 V (vs Ag/AgCl) obtained at 22° C. for 2⁺ in Nafion on a 3 mm diameter glassy carbon disc electrode in H₂O (0.1 M Na₂SO₄), exposed to white light, 7 W, 3 cm away from the light source:
(A) Nafion doped with 2⁺,
(B) Nafion doped with Ru(bipy)₃²⁺ and
(C) Nafion doped with 2⁺ and Ru(bipy)₃²⁺.

FIG. 14: shows the photocurrent generated from excitation by controlled potential electrolysis at 1 V (vs Ag/AgCl) of Nafion coated electrode doped with [Mn₄O₄L₆]⁺ and Ru(bipy)₃²⁺ using monochromated wavelengths of light (black trace) and Nafion only coated electrode (grey trace). Insert displays previously described photo excitation of Nafion coated electrode doped with [Mn₄O₄L₆]⁺ only.

FIG. 15 is a schematic depiction of the cross-sectional arrangement of and embodiment of the photo-anode, showing the following layers:
(i) bottom-most layer: a conducting substrate such as a conducting glass
(ii) middle-layer: a semi-conducting layer, such as a nanoporous titanium dioxide, bearing on its upper surface a suitable sensitizing dye
(iii) top-most layer: a Nafion layer containing catalytic groups according to the invention.

FIG. 16 is a schematic representation of a photo-electrochemical cell capable of water-splitting when illuminated with sunlight.

FIG. 17 is a schematic of the an embodiment of the present photo-anode within a photo-electrochemical cell capable of water-splitting when illuminated with sunlight

FIG. 18 is a schematic depiction of a comparable titanium dioxide photo-anode within a photo-electrochemical cell capable of water-splitting when illuminated with sunlight

FIG. 19 is a two electrode, controlled potential electrolysis at 0 V obtained at 22° C. for nanoporous TiO₂ in H₂O (0.1 M Na₂SO₄), exposed to white light, and then light with wavelengths less than 455 nm filtered out.

FIG. 20 is a two electrode, controlled potential electrolysis at 0 V obtained at 22° C. for nanostnictured TiO₂ on conductive glass sensitized with dye, and coated with Nafion in H₂O (0.1 M Na₂SO₄), exposed to white light, and then light with wavelengths less than 455 nm filtered out.

FIG. 21 is a two electrode, controlled potential electrolysis at 0 V obtained at 22° C. for nanostructured TiO₂ on conductive glass sensitized with dye, and coated with Nafion doped with 1 in H₂O (0.1 M Na₂SO₄), exposed to white light, and then light with wavelengths less than 455 nm filtered out.

FIG. 22 is a two electrode, controlled potential electrolysis at 0 V obtained at 22° C. for nanostructured TiO₂ on conductive glass (grey) sensitized with dye, and coated with Nafion (dashed) doped with 1⁺ (black) in H₂O (0.1 M Na₂SO₄), exposed to white light 150 mW/cm², and then light with long wave filters as labelled.

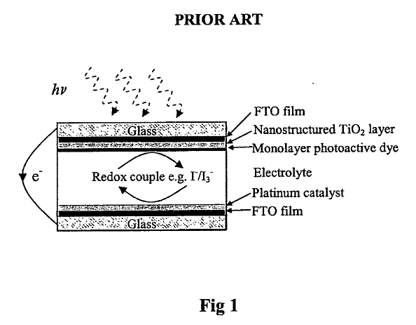

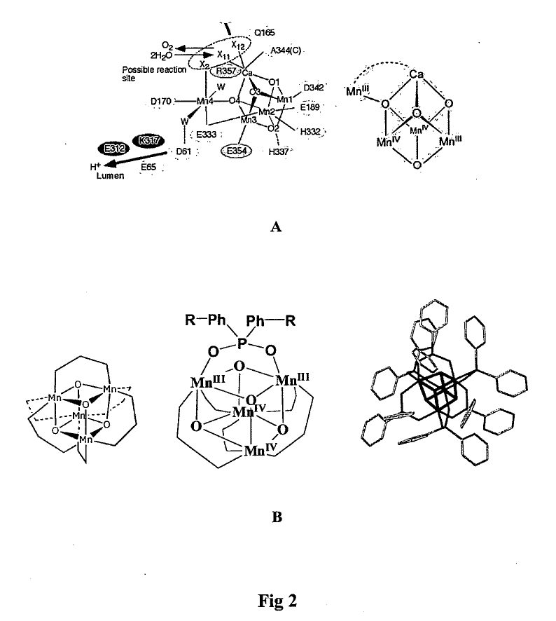

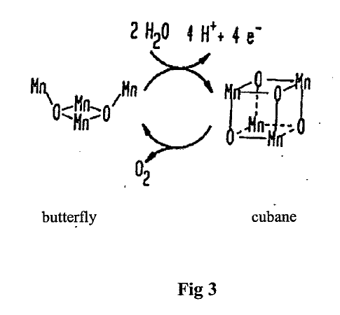

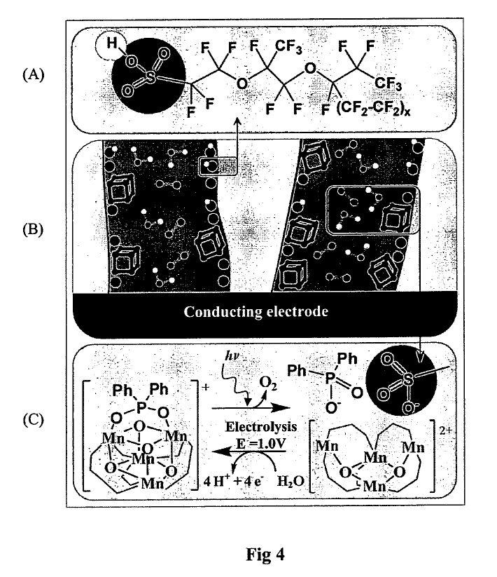

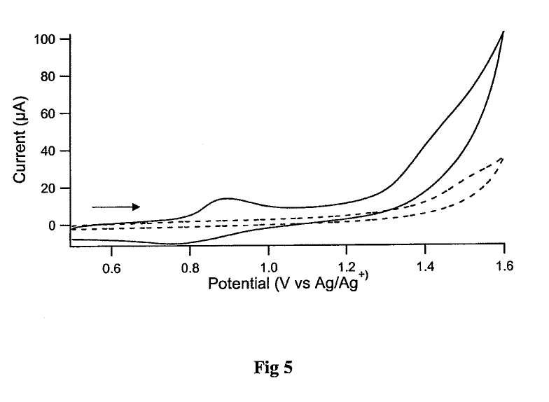

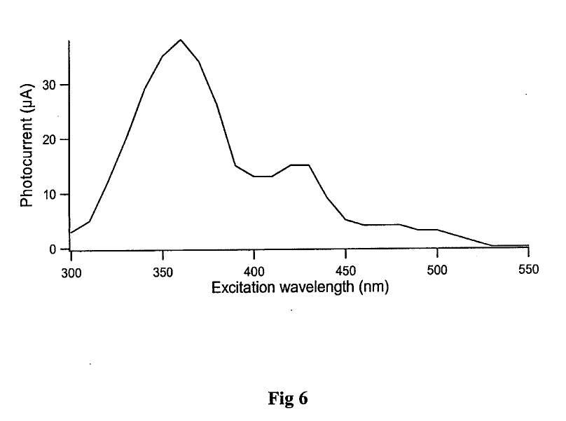

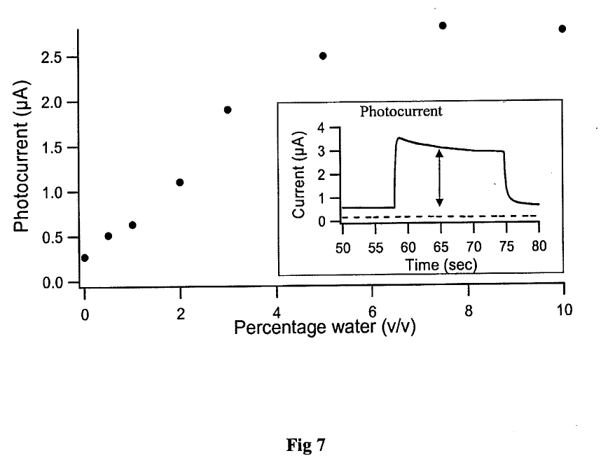

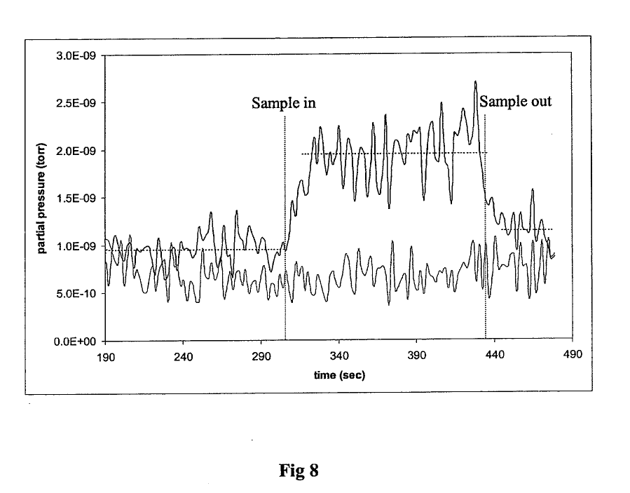

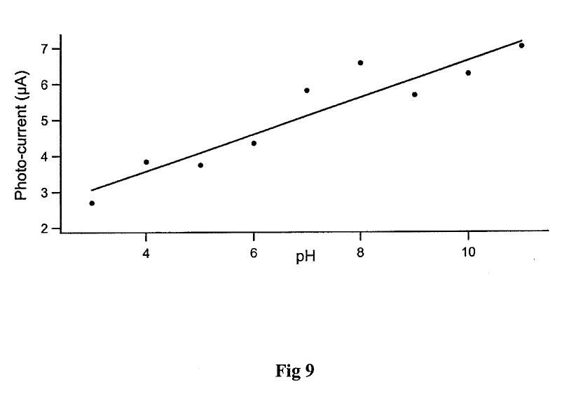

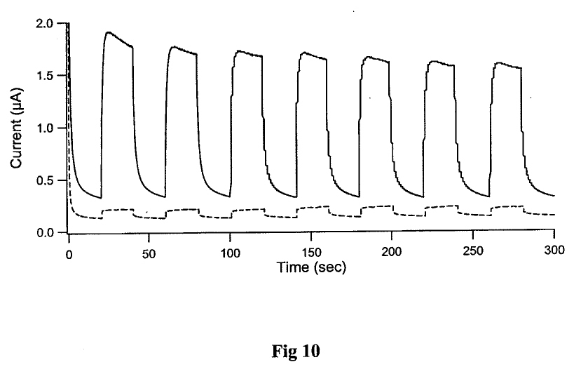

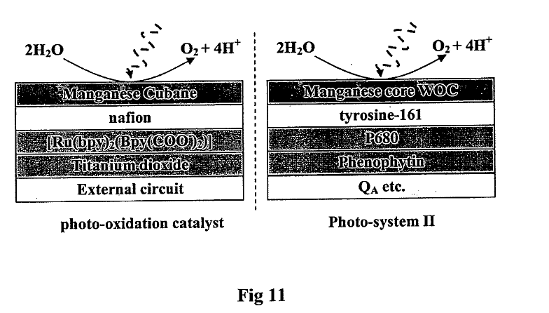

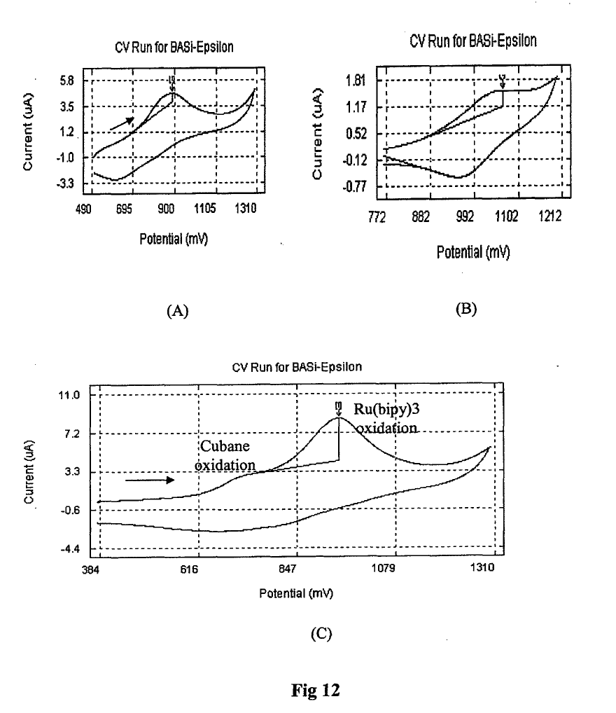

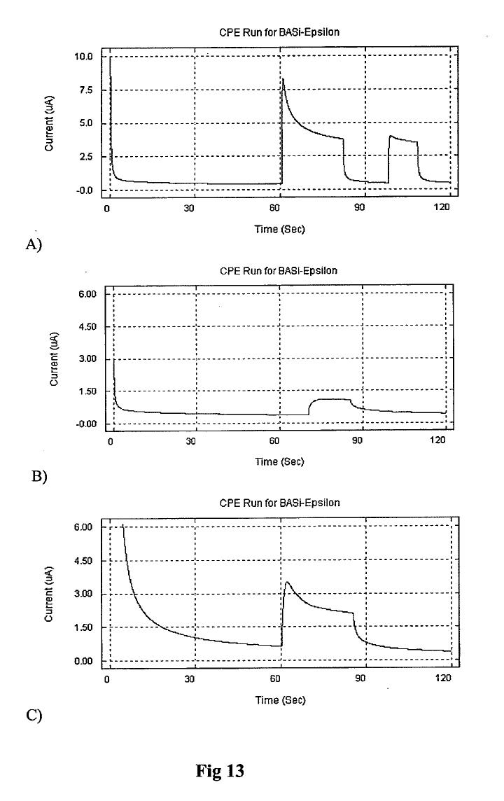

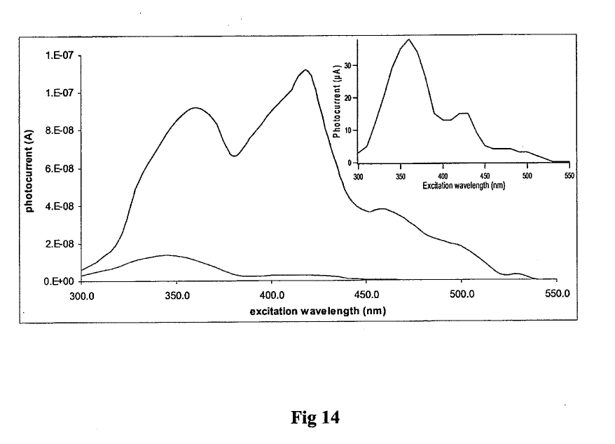

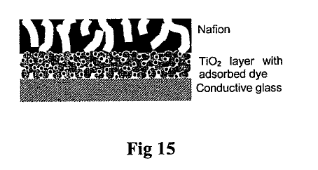

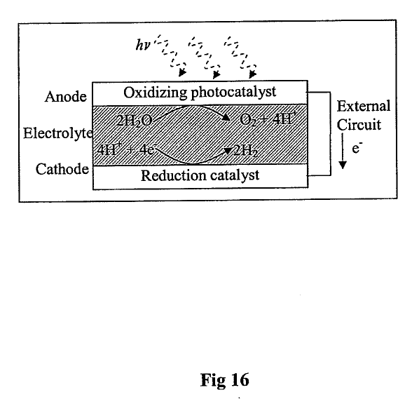

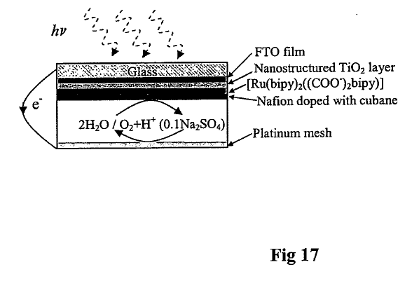

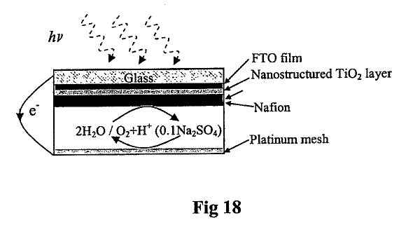

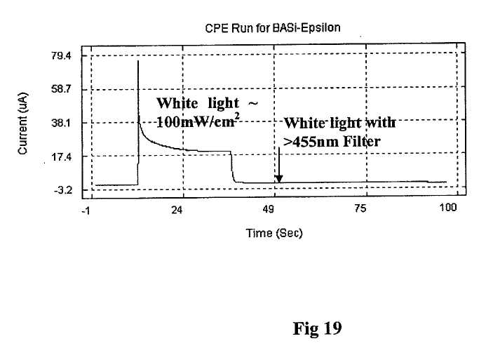

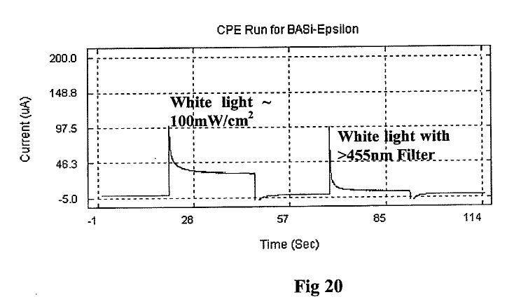

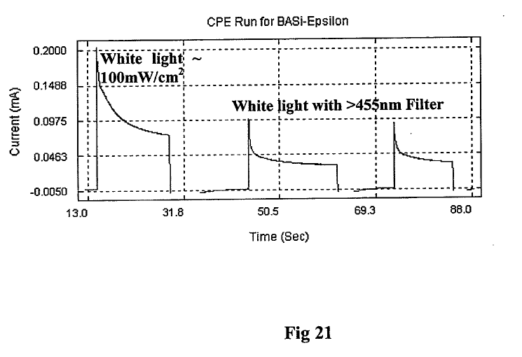

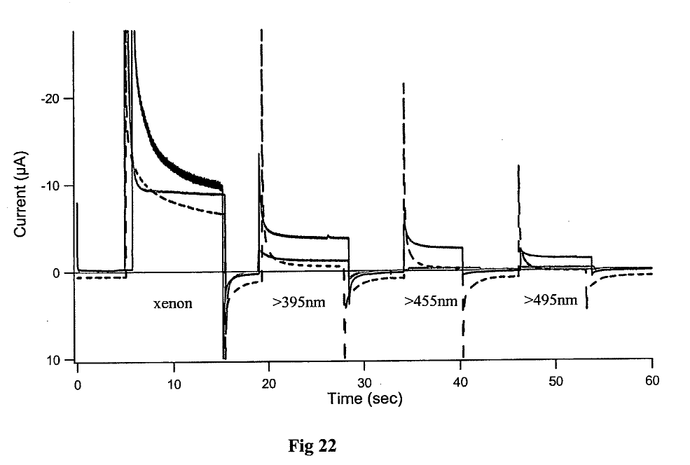

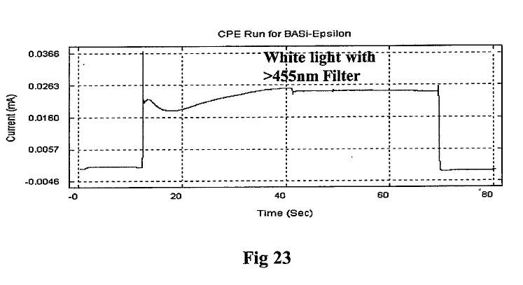

FIG. 23 is a two electrode, controlled potential electrolysis at 0 V obtained at 22° C. for an equivalently sized and constructed Graetzel cell comprising TiO₂. Sensitizer N719 in I⁻/I₃⁻ in CH₃CN, Pt counter electrode, according to the set-up depicted in FIG. 1. The >455 nm cut-off filter was applied after about 42 seconds.

### DESCRIPTION OF PREFERRED EMBODIMENTS OF THE INVENTION

The catalytic activity of manganese-oxo clusters is used to catalyse the oxidation of water for the generation of hydrogen and oxygen and electrical power. The catalytic groups are tetra-manganese-oxo clusters that are insoluble and/or unstable in aqueous solution to the extent that the cluster is unable to efficiently catalyse the photo-oxidation of the water. The catalytic tetra-manganese-oxo groups can be referred to as cubanes. In order to demonstrate the catalytic activity, two variations of tetramanganese-oxo cubanes [Mn₄O₄L₆] have been investigated as catalytic groups:
¹ [Mn₄O₄L¹₆] (L¹=diphenyl phosphinate, (C₆H₅)₂PO₂); and
² [Mn₄O₄L²₆] (L²=bis(p-methoxyphenyl)phosphinate, MeO(C₆H₅)₂PO₂)

Catalytic group 1 has tetrahedral symmetry in its core which lacks Jahn-Teller distortions, indicating delocalized valence electrons amongst the four identical Mn sites, in both the solid state and solution phases³. Catalytic group 2 displays C₂ᵥ point symmetry with pairs of discrete Mn(III) and Mn(IV) sites resulting in preferential release of two of the four corner oxygens⁴. This distortion is caused by greater electron donating properties of the methoxy-group of L² that causes electron repulsion in the core increasing the yield of ligand photo-dissociation. Catalytic groups 1 and 2 are used as examples and it should be understood that other manganese-oxo clusters species capable of catalysing the photo-electro-oxidation of water could also be used.

When dissolved in organic solution, the cubane catalytic groups can act as a powerful catalyst for the oxidation of a range of organic reagents including thioethers, hydrocarbons, alkenes, benyzl alcohol and benzaldehyde⁵. The proposed mechanisms for these oxidations, involves the disruption of the binding of a phosphinate ligand thereby facilitating the temporary co-ordination of the reagents to a manganese within the cubane core. Investigations into the reactivity and catalytic potential of cubane catalytic groups have previously been limited to organic systems due to the hydrophobic shell that the phenyl phosphinate ligands form around the cubane core. For example, experiments in CH₃CN have shown that in greater then 10% water (v/v) dissolved cubane breaks down in a matter of minutes. At 2% water in CH₃CN, dissolved cubane breaks down over a period of approximately 48 hours.

The present invention provides a means for facilitating the interaction of manganese-oxo cubane groups with water. The cubanes are placed in an environment that is thought to minimise chemical reactions that lead to degradation of the cubanes during operation. The environment is therefore one in which the cubane catalytic groups are stable in the presence of water and in which they are able to interact with water molecules that come into contact with the catalytic groups. The stability is imparted by a support substrate that incorporates water and which permits the assembly of the cubanes.

One such support substrate is a perfluorosulfonate cation exchange polymer developed by Dupont and sold under the trade mark Nafion®. (All references to Nafion throughout this specification refer to the Dupont trade mark). The molecular structure of Nafion is shown in FIG. 4A. The —CF₂CF(CF₃)O— polymer backbone forms a hydrophobic solid membrane that is penetrated by aqueous channels lined with the hydrophilic ionisable sulfonic acid groups, —SO₃H Investigations into the sub-structure of Nafion coatings on solid surfaces have revealed that the polymer layers contain these hydrophilic channels throughout the otherwise hydrophobic regions of the membrane. These channels allow the diffusion of small molecules such as water.

While Nafion is the preferred support substrate, other polymers and porous inorganic hybrid materials could be used provided the polymer or material is able to incorporate water and supplies a hydrophobic environment for the catalytic manganese-oxo cluster. Other supports include, for example, Nafion, amberlite, polyacetylene, polypyrrole, polyaniline, various organic acids such as carboxylates, sulfonates, phosphonates, phosphinates, various types oxide, metallic and quantum dot nanoparticles (e.g., silica, titania, CdSe, Au, etc.) functionalised with anionic groups such as sulfonates, phosphonates, phosphinates and carboxylates. For convenience, the invention is described with particular reference to Nafion.

The water can be brought into contact with the catalytic groups in the support substrate by any suitable means. For example, the water could be passed over the support substrate surface at a rate which allows the water to be incorporated into the channels in the support. In one embodiment, the support substrate is immersed in an aqueous solution. The aqueous solution can be a solution from which the water is preferentially removed (i.e. solid liquid separation. For example, where the aqueous solution is salt water or sea water the water could be removed leaving the salt behind (i.e. desalination).

It has been found that the present catalyst works effectively in salt water. It is known that at 1.35 V chloride ions in the salt water react to form chlorinated by-products which are undesirable and render the desalination process energy intensive. The potential applied in these devices is lower than 1.35 V to avoid these undesirable reactions.

The size and distribution of the pores or channels in the Nafion polymer is highly dependent on the preparation method of the membrane⁶. It has been shown that pore sizes in membranes cast from solution are influenced by the rate of evaporation of the casting solvent and the presence of water. The Nafion membrane acts as an interface between the hydrophobic cubane catalyst groups and the aqueous solution in which the support is preferably immersed. The support substrate is thought to overcome the hydrophobicity of the catalytic groups by suspending the cubanes in the hydrophobic pockets or regions of the polymer. Whilst in these regions, the cubanes are believed to be able to interact with the water molecules that diffuse down the hydrophilic channels formed in the membrane.

FIG. 4B is a schematic of the cubane catalyst groups (for clarity, shown without ligands) assembled at the interface of the hydrophobic regions and the hydrophilic channels. The cubane molecules are likely drawn into the channels by ion exchange, displacing protons and remaining loosely associated with sulfonate anions.

FIG. 4C shows the proposed catalytic photo-electrolysis cycle of the cubanes within the support. Upon photo-excitation of the Nafion-supported cubane a phosphinate anion is dissociated thereby lowering the barrier to release of molecular O₂ from the corner oxo bridges. Upon photo-dissociation of a phosphinate ligand, oxygen is evolved from the cubane. The de-oxygenated “butterfly” cubane core that is thought to be formed, catalyses the oxidation of water. The following proposed reaction scheme represents one cycle:

(i) [Mn₄O₄L₆]⁺O₂+L⁻+[Mn₄O₂L₅]²⁺

(ii) [Mn₄O₂L₅]²⁺+L⁻+2H₂O (4H⁺+4 e⁻)→[Mn₄O₄L₆]⁺

The pair of released oxygen atoms are replaced by two water molecules bound to the core which enables electrochemical oxidation by the supporting electrode and proton release into solution, completing one catalytic cycle.

It is proposed that in some embodiments, the support substrate does more than just provide an interface for the cubane and water molecules to interact. The evolution of oxygen from the cubane core requires an increase in the flexibility of the core. This flexibility is imparted by the dissociation of a phosphinate ligand. Previously it has been reported that, in the condensed state, photo-dissociation is not observed; however, cubanes supported by Nafion are able to release a phosphinate ligand and act as water catalysts. This is thought to be because reactive catalytic intermediates that form within the support substrate are stabilised by the support structure. The reactive catalytic group intermediates may be held within the support substrate by a combination of hydrophilic, hydrophobic and electrostatic forces that facilitate the interaction between the reactants and catalyst and which prolong the lifetime of intermediates thereby increasing their opportunity to react.

It is thought that when Nafion is used as the support, the ionisable sulphonate groups may play an important role in stabilizing the catalytic group intermediates (shown on the right hand side of the reaction scheme of FIG. 4C). The sulfonate anions of the Nafion appear to provide a means of slowing the rebinding of the phosphinate ligand in their normal bridging geometry after the photo-dissociation process, previously shown to inhibit O₂ evolution in condensed phases. The sulphonic acid/sulphonate groups potentially protonate the dissociated phosphinate groups (which are more basic), thereby slowing rebinding of the ligand. Alternatively, binding of exposed manganese atoms by sulphonate groups may slow or even prevent re-binding of phosphinate ligands thereby encouraging ligand dissociation and subsequently oxygen evolution.

The Nafion support has sulphonic acid groups, however, other ionisable groups could be provided. Furthermore, the group need not supply a negative charge and instead there might be a positive charge introduced that provides the required hydrophilicity within the membrane, e.g. via an amine group.

In organic solution the cubane is unstable in the presence of even small amounts of water thus the support of reactive intermediates by sulphonate groups may also play an important role in preventing rapid ligand exchange with excess water molecules. The hydrophobic pockets or regions in which the cubanes assemble appear to protect the cubane from excess water. The immobilization of the cubane in the hydrophobic regions or domains of the Nafion is also thought to be important in trapping any further dislodged ligands in close proximity to the cubane core, facilitating rapid rebinding and reducing degradation of the cubane compared to the degradation of the cubane catalytic groups observed in bulk solution.

In one example of the invention, a half-cell coated with Nafion containing cubane has been operated for 7 hours with only a 10% drop in photo-current. This is equivalent to more than 150,000 catalytic cycles. The few reported examples of molecular water oxidation produce a few tens of cycles or use strong chemical oxidants to contribute an O atom to the O₂ product. For the cubane doped catalyst of the present invention, both atoms in the O₂ derive from water molecules and no sacrificial reactant oxidant is required to drive the process. The catalyst is regenerated by an applied external electrical potential; however, other means of regenerating the catalyst are within the scope of the invention.

The catalyst of the present invention can be incorporated into a photo-electrochemical cell. Upon oxidation of water at the photo-anode hydrogen protons are be generated which would be reduced to hydrogen gas at a counter electrode. The cell could be driven either by a photo-anode such as dye sensitised semiconductor (e.g. TiO₂) or an external potential.

The dye sensitised semiconductor acts as a chemical/photo-electrical relay system. The cubane groups can interact favourably with the photo-electrochemical relay systems to improve the overall efficiency of the catalysis. A thin layer of the catalyst can be in contact with the photo-electrochemical relay system to extend the capacity and increase the efficiency of the catalyst. Preferred examples of such relay systems include ruthenium N-donor dyes such as Ru polypyridyl dyes that absorb visible light and then electrochemically oxidize the tetra-manganese-oxo cubanes. This enhances the efficiency with which light in the visible region is converted into chemical energy overall, since manganese-oxo clusters such as cubanes typically do not absorb visible light strongly.

The sequence of electron transfer that occurs in Photo-system II is schematically depicted in a layered form in FIG. 11 (right-hand picture), with electrons moving sequentially from the top-most layer down to the bottom-most layer.

In the photo-anode according to an embodiment of the present invention, a similar sequence occurs, albeit via different components (left-hand image of FIG. 11). As in the right-hand image, the electrons move sequentially down these layers, from the top-most to the bottom-most layer. In broad principle therefore, the photo-anode of the present invention mimics the processes that occur during water-oxidation catalysis in Photo-system II.

The photo-anode can be used in tandem with an electrolyser to produce an electrochemical cell. An electrochemical cell containing according to an embodiment of the present invention consequently appears to offer a highly efficient method of splitting water using solar illumination only, i.e. without the need for an applied potential. The energy from the cell could be recovered for further use. The oxygen and hydrogen generated from the cell could be passed directly into a fuel cell to generate further power.

The invention will now be described by way of a number of examples which are not intended to be limiting in any way.

### Example 1

### Doping of the catalytic Groups into the Support Substrate

### Stationary Voltammetry Oxidation of 1 and 2 in Nafion Membranes

The cationic cubane catalyst 1⁺ was doped into a Nafion film by immersion of a cast Nafion membrane in a solution of [Mn₄O₄L′₆]ClO₄ (complex 1⁺) in acetonitrile (CH₃CN). Voltammetric detection of the redox transition 1/1⁺, previously observed for 1 in CH₂Cl₂ solvent (0.1 M Bu₄NPF₆) confirmed the doping of the cubane into the Nafion film and established charge transfer between the catalyst and underlying conducting electrode.

2⁺ was incorporated into the Nafion membrane by immersing the cast membrane in a solution of 2⁺ (0.5 mM in CH₃CN). Once incorporated, doping success was observed by conducting cyclic voltammetry experiments on the doped membranes immersed in a working solution of H₂O (0.1 M Na₂SO₄) and cycling around the 2/2⁺ redox process. The oxidation couple is not observed for membranes doped with solutions of 2.

The electrochemically generated 2 in the Nafion membrane appeared to be stable and retained in the Nafion membrane. From these observations it appears that 2⁺ is taken up into the Nafion by cation exchange with the protons of the sulphonic acid functional groups within the Nafion membrane channels. We propose that although 2 can not be taken up into the membrane, when generated in the membrane by reduction of 2⁺, the aqueous working solution appears to trap 2 within the hydrophobic pockets or regions of the Nafion polymer.

The oxidation of 2 supported in Nafion on the electrode surface in H₂O (0.1 M Na₂SO₄), is well defined at a scan rate of 50 mV/s. The potential at which the oxidation and reduction process occur is difficult to define due to movement of the potential after cycling and exposure to light. Nevertheless, the Nafion support appears to provide good electrical contact between the cubane and the electrode.

### Example 2

### Evidence of the Catalytic Groups Catalysing the Oxidation of Water

### Stationary Voltammetry Catalysis of Water Oxidation

In solution, no further oxidation processes were observed for 2 between 1 V and the solvent limit of CH₂Cl₂ (0.1 M Bu₄NPF₆) at approximately 2 V vs Ag/AgNO₃. FIG. 5 displays the oxidation of 2⁺ suspended in Nafion immersed in aqueous 0.1M Na₂SO₄ and sweeps up towards the water oxidation potential (1.4-1.6 V). As the potential approaches the water oxidation potential the current from a 2⁺ doped Nafion coated electrode increases at a significantly steeper gradient than the current of the Nafion coated electrode and the bare electrode.

At the oxidation potential of water in a 10% water/CH₃CN (0.1 M Bu₄NNO₃) solution the current from the Nafion doped with 2⁺ electrode is significantly greater than the Nafion coated and uncoated electrode, peaking at approximately 1650 mV. Below this potential the current from an uncoated glassy carbon electrode in 10% water CH₃CN (0.1 M ^{t}Bu₄NNO₃) is greater than the current observed for a Nafion doped with 2⁺ electrode, and a Nafion only coated electrode. As the potential sweeps beyond the water oxidation potential towards the solvent limit the current of the uncoated electrode again becomes greater than the Nafion doped with 2⁺ electrode. This suggests that the Nafion coating blocks the water and CH₃CN reaching the electrode surface.

These experiments suggest that Nafion doped 2⁺ increases the rate of water oxidation (oxidation current observed at the water oxidation potential) compared to a Nafion coated or an uncoated glassy carbon electrode. Thus 2⁺ appears to be able to catalyse the oxidation of water when supported in a suitable polymer such as Nafion. As 2 and 2⁺ are both completely insoluble in water, the Nafion membrane provides an interface for the cubane to interact with the water. It is proposed that the cubane is held in the Nafion membrane where it is exposed to and is able to react with the water molecules that diffuse into the sulphonic acid/sulphonate lined channels.

After the cubane oxidation, the current obtained by cyclic voltammetry of the Nafion doped with 2⁺ steadily increases toward the water oxidation potential. As observed in controlled potential experiments the total photo-excited current generated by Nafion only increases as the potential is increases towards the water oxidation potential. In contrast the photo-current from 2⁺ in Nafion (total excited current minus background current) increases up to 1 V and then levels off and is stable from 1 V onwards (up to 1.2 V). The 1 V peak in photo-current corresponds to the complete oxidation of the cubane. Thus in the presence of excess water the photo-current appears to be limited by the presence of oxidized cubane.

The oxidation potential of the oxidised cubane is not high enough for water oxidation to occur via four one electron steps (required potential of 2.42 V vs SHE). Assuming the dissociation of a ligand is required for the release of O₂, two of the manganese atoms would be exposed to the supporting solution which could facilitate H₂O or OH coordination to an individual or a pair of manganese atom lowering the oxidizing potential required. However, as sustained water oxidation is not observed for simple Mn₂O₂ structures it is the unique properties of the tetra-manganese structure that is able to overcome the water oxidation activation barrier. This may be facilitated by bound OH₂ molecules interacting with three manganese atoms analogous to how the core oxygen ligands co-ordinate. The electron delocalization within the cubane core is also likely to be an import feature in facilitating the removal of multiple electrons from the water molecules.

### Example 3

### Peak Excitation Wavelengths and Light Intensity

Monochromated light was used to determine the peak wavelength for photo-excitation of 2⁺ in Nafion. The photo-excited current (total excited current minus the background current) was measured over a range of excitation wavelengths, using a small Nafion coated platinum electrode. The Nafion only coated electrode showed relatively low photo-excitation with a small excitation peak at 350 nm. The Nafion doped with 2⁺ displayed significant photo-current from 325 nm to 525 nm (FIG. 5).

The peak excitation of the Nafion doped with 2⁺ was observed at 360 nm. The peak corresponds to the main ligand to metal charge transfer absorption observed in the electronic spectra of the cubane in solution. Furthermore the peak excitation corresponds to the peak in difference in absorption between 2⁺ and 2⁷, suggesting that the activating energy provided by the light corresponds to the peak charge transfer of the oxidized cubane (2⁺). This adds further support to the hypothesis that it is the oxidized form of the cubane that is able to photo-catalyse the oxidation of water.

The intensity of the photo-current is dependent on the intensity of irradiation light. The intensity of photo-current steadily decreases as the electrode is moved further away from the light source. The dependence of the photo-current was also examined as a function of the applied potential and found to match the dark oxidative trace observed following prior reduction of the cubane, as measured previously by cyclic voltammetry. This behaviour indicates that the cubane is reduced during photolysis, as expected based on the formation of O₂.

On initial exposure of the cubane doped Nafion to light there is a short peak in photo-current that rapidly settles back to the steady photo-current. This initial spike becomes less evident after prolonged or repeated exposure to light. Thus photo-current appears to be subject to a physical rate limiting process. Some possibilities for this include diffusion of water to the cubane or perhaps the incorporation of oxygen and rebinding of the dissociated ligand.

### Example 4

### Photo-Reaction in Water

The electronic spectrum of Nafion on fluoride tin oxide (FTO) coated glass and Nafion on FTO coated glass doped with 2⁺ were measured in a spectro-electrochemical cell filled with H₂O (0.1 M Na₂SO₄). The Nafion 2⁺ was then reduced electrochemically to Nafion 2 allowing the electronic absorption spectra of 2 in Nafion to be measured. As in the solution phase 2⁺ in the Nafion layer has a greater electronic absorption than 2 over the charge transfer range 325 nm to 425 nm.

A layer of Nafion doped with 2⁺ on FTO in H₂O (0.1 M Na₂SO₄) was exposed to white light for 2 hours. The electronic spectrum was measured before and after the light exposure. After light exposure, in water the electronic absorption of the cubane had reduced absorbance over the charge transfer region, resembling the more reduced form of the cubane than the oxidized cubane. These experiments suggest that under light excitation in water the oxidized cubane supported in Nafion is reduced. In conjunction with earlier experiments that demonstrated that the observed photo-current results from the oxidation of water by the oxidized cubane (2⁺), this experiment suggest that the cubane is reduced in the process and thus the catalytic cycle is completed by the re-oxidation of the cubane by the applied potential.

### Example 5

### Photo-electro-catalysis of Water

In CH₃CN (0.1 M Bu₄NPF₆) a Nafion membrane doped with 2⁺ coated electrode, displays little to no photo-current. In CH₃CN (0.1 M Bu₄NPF₆) containing 10% (v/v) water, the same electrode preparation displays a strong photo-current upon exposure to light.

An identical experiment was conducted for a Nafion-only coated electrode and no significant photo-current was observed in CH₃CN or in CH₃CN containing 10% water. Thus the photo-current is only observed in the presence of the cubane and water. Furthermore, the replacement of water by acetonitrile (and 0.1 M Bu₄NPF₆ electrolyte) eliminates the photo-current, while back titration with water restores the photo-current to the same level when % (v/v) water is added to the acetonitrile. FIG. 7 illustrates the relationship between the photo-current and the proportion of water present in an acetonitrile electrolyte.

A Nafion membrane and a cubane doped Nafion membrane on a 3 mm diameter glassy carbon electrode, were photo-excited in water (50% H₂¹⁸O) (0.1 M Na₂SO₄) with an applied potential of 1 V (vs Ag/AgCl) for one hour. Measurements at m/z=36 revealed a significant increase in the concentration of ³⁶O₂ in the working solution after exposure to the illuminated cubane (FIG. 8). Control experiments using only Nafion with no cubane revealed no increase in ³⁶O₂ after one hour of illumination with applied potential of 1V (vs Ag/AgCl). The formation of ³⁶O₂ only in the presence of water adds further evidence to the proposal that H₂O is the electron donor responsible for the observed photo-current.

Further evidence identifying bulk water as the source of the photo-current comes from the observation that the photo-current increases linearly with solution pH between pH 2 and pH 12 in an unbuffered solution (FIG. 9). This behaviour is well documented for electrolysis of pure water, and theoretically attributed to the dependence of the electrochemical potential required to oxidize water (which decreases 59 mV per unit pH).

The photo-current was consistently observed using a range of different electrolytes (Na₂SO₄, NaF, Bu₄NPF₆, Bu₄NClO₄) and for cubane-doped Nafion membranes deposited on a range of conductive surfaces (glassy carbon, Pt, FSnO₂ coated glass). No significant photo-current was observed for undoped Nafion-coated electrodes, or doped with NaClO₄ in acetonitrile or doped with sodium diphenyl phosphinate in acetonitrile. Thus, the photo-current requires only the presence of the cubane complex, the support substrate and water.

### Example 6

### Photo-Excited Controlled Potential Electrolysis

When poised at 1 V (vs Ag/AgCl), exposure of a Nafion doped with 2⁺ coated electrode immersed in aqueous 0.1 M Na₂SO₄, to light causes a dramatic increase in current. This photo-current immediately decreases once the light source is removed and rapidly reappears upon re-exposure (FIG. 10). As discussed previously the cubane is only incorporated into the Nafion membrane in the positively charged oxidized form (2⁺), thus in a freshly doped membrane the majority of the cubane should be in the oxidized state and any neutral cubane present will be rapidly re-oxidized. Thus the activation energy provided by the light is either activating a previously unobserved oxidation of the cubane (2⁺→2ⁿ⁺¹+ne⁻) or activating a chemical reaction between the cubane and the working solution.

Over a period of two hours, the photo-current generated from the Nafion doped with 2⁺ electrode is stable at over six times the current of the light exposed Nafion coated electrode. By measuring the electronic absorption of the doping solution before and after doping, the amount of cubane within the Nafion membrane was estimated at 6±2 ng. If the photo-current was arising from a photo-excited oxidation of the cubane alone for this amount of cubane a current of greater than 1 μA would rapidly decreased toward zero on the seconds time scale. Thus the sustained current suggests that there is an external source of electrons other than the cubane.

To investigate the potential involvement of the SO₄⁻ ion as an electron acceptor in the generation of photo-current, these experiments were repeated using H₂O (0.1 M NaF), (F₂+2e⁻<−>2F⁻, E°/V 2.644 (vs Ag/AgCl)). Changing the electrolyte had no detectable effect on the photo-current. The experiments were also repeated using a platinum electrode and FTO conductive glass electrode and equivalent photo-currents were observed. Equivalent photo-excitation experiments were conducted with Nafion coated electrodes doped with solutions of acetonitrile alone, NaClO₄ dissolved in acetonitrile and diphenyl phosphinate dissolved in acetonitrile. No significant photo-current above that observed for the Nafion alone was observed. Thus it appears that the presence of the cubane core is essential for the generation of the observed photo-current.

### Example 7

### Di-oxygen (O₂) Generation

A Nafion coated electrode was exposed to light at 1 V for 1 hour in a 50% H₂¹⁸O solution with 0.1 M Na₂SO₄. The treated solution was passed through a MIMS and no increase in ³⁶O₂ above the natural concentration in untreated water was detected. An equivalent experiment using a 2⁺ doped Nafion coated electrode immersed in the 50% H₂¹⁸O solution with 0.1 M Na₂SO₄, resulted in the formation of a detectable increase in the amount of ³⁶O₂. This experiment provides evidence that the cubane doped Nafion is able to catalyse the oxidation of water to dioxygen when exposed to light with an external potential of 1 V vs Ag/AgCl.

### Example 8

### O₂ Generation

A custom build gas collecting cell was used to investigate the oxygen producing capability of the cubane in Nafion. The gas cell was completely filled with H₂O (0.1 M Na₂SO₄) and a 100×150 mm Pt plate electrode was used as the working electrode. After 7.5 hours of light excitation a working electrode coated in Nafion held at 1 V (vs Ag/AgCl) produced no observable gas bubbles. When the working electrode was coated with Nafion doped with 2⁺ and exposed for 7.5 hours to white light at 1 V (vs Ag/AgCl), gas bubbles were observed evolving of the electrode surface and 32 μl of gas was collected from the working electrode gas collection chamber.

At 25° C., 1 atm, 32 μl of gas is equivalent to 1.31 μmol, 42 μg of O₂. The total charge recovered from the experiment was 0.488 coulombs, equivalent to 5.1 μmol of electrons. Assuming that the gas produced is oxygen from water, the amount of oxygen gas produced from this charge would be 1.27 μmol, 41 μg of O₂. Thus the amount of gas collected from the experiment was equivalent to the charge generated.

By measuring the electronic absorption of the doping solution before and after doping, the amount of 2⁺ in the Nafion membrane on the Pt plate was estimated at 15±5 ng. Thus if 7.7 pmols of 2⁺ produced approximately 1.3 μmol of O₂ over 7.5 hours then approximately 6±2 O₂ molecules were produced per second per cubane molecule in with over 150,000 turnovers per cubane.

### Example 9

### Solid Layer Electrochemistry

Due to the complexity of the Nafion system, the electrochemistry of the cubane in aqueous solution was further investigated using a solid layer of cubane cast onto the electrode surface in contact with an aqueous solution of 0.1 M Na₂SO₄.

The solid layer of cubane on the electrode displays very weak photo-excitation even when the amount of cubane present is greater than 100 times the amount estimated to be doped into the Nafion membrane. This adds further support to the importance of the support substrate structure in facilitating photo-catalysis.

### Example 10

### The Advantage of Using a Chemical/photo-electrochemical Relay

To demonstrate the advantage of using a photo-electrochemical relay, Nafion membranes were doped with both 2⁺ and [Ru(bipy)₃]²⁺ by immersing in a solution of 2⁺ in CH₃CN for 20 minutes, then in a solution of [Ru(bipy)₃]²⁺ in H₂O for a further 20 minutes. Cyclic voltammetry and photo-electrochemistry was conducted using an aqueous 0.1 M Na₂SO₄ working solution, with a platinum counter electrode and a Ag/AgCl reference electrode.

As shown in FIG. 12, the oxidation potential of [Ru(bipy)₃]²⁺ in Nafion is approximately 200 mV greater than that of [Mn₄O₄L₆]⁺.

2<−>2⁺+e⁻ Equation I: (FIG. 10 top left)

[Ru(bipy)₃]²⁺->[Ru(bipy)₃]³⁺+e⁻ Equation II: (FIG. 10 top right)

When both compounds are doped into the membrane the oxidation peaks of both compounds are observed. However, the coupled reduction process for the [Ru(bipy)₃]²⁺ is poorly defined with the main reduction process occurring at the potential corresponding to reduction of 2⁺ to 2 at (˜650 mV). This suggests that [Ru(bipy)₃]³⁺ is being chemically reduced by [Mn₄O₄L₆] within the membrane.

[Ru(bipy)₃]³⁺+2→[Ru(bipy)₃]²⁺+2⁺ Equation III: (FIG. 10 bottom)

Irradiation of [Ru(bipy)₃]²⁺ with visible light causes it to be oxidized to [Ru(bipy)₃]³⁺. As the oxidized ruthenium compound appears to be able to oxidize the cubane within the Nafion membrane, we propose that irradiation of the double-doped Nafion with visible light should drive Equation II and subsequently Equation III, resulting in the generation of [Mn₄O₄L₆]⁺.

As described previously the catalytic oxidation of water is completed by re-oxidation of the cubane to [Mn₄O₄L₆]⁺. These findings suggest that the applied potential could be replaced by a dye with a suitable redox potential that is photo-oxidised and in turn oxidizes the cubane completing the catalytic cycle.

FIG. 13(A) shows the irradiation of 2⁺ doped Nafion results in the generation of a photocurrent, with water as the electron donor for the observed current. Nafion doped with [Ru(bipy)₃]²⁺ alone (FIG. 13(B)) generates only a small amount of photocurrent. The double-doped membrane generates a significant photo-current, presumably primarily resulting from the cubane oxidizing water.

Further investigation of the photo-excitation of the double doped Nafion membrane was undertaken using a monochromated light source. A new photo-excitation peak was observed for the double doped membrane at 430 nm. This photo-excitation peak (FIG. 14) matches the electronic absorption peak for [Ru(bipy)₃]²⁺, suggesting [Ru(bipy)₃]²⁺ is absorbing visible light at this wavelength and that light excited energy is being transferred to the cubane molecules providing the activation energy required to catalyse the oxidation of water.

By incorporating a chemical relay system, catalysis is able to occur at much longer wavelengths than possible for the cubane alone. This finding opens the possibility of using a range of photo-active dyes to increase the range of visible light that can be used to activate the photo-assisted oxidation of water by the cubane.

### Example 11

### Photo-anode and Photo-electrochemical Cell Assembly Using the Chemical/photo-electrochemical Relay System

FIG. 15 illustrates the conceptual layout of a photo-electrochemical cell in which illumination by sunlight results in the water electrolyte being split into hydrogen and oxygen.

In order to prepare the photo-anode, nanoporous TiO₂ was prepared from a slurry of P25 TiO₂, water, TritonX and acetyl acetone. The slurry was deposited on to FTO conductive glass and spread with a glass rod. Films were sintering at 450° C., after depositing and directly before sensitization. Sintered films were cooled to 80° C. and immersed in a 0.5 mM solution of [Ru(bipy)₂(bipy(COO⁻)₂)] dye in acetonitrile/tertiary butanol.

Sensitized solutions were rinsed in acetonitrile before a layer of Nafion was deposited over the dye layer. The electrode was dried at 130° C. before being immersed in a solution of 1⁺. The resulting device has the cross-sectional arrangement as depicted in FIG. 16.

FIG. 17 depicts a solar water-splitting electrochemical cell incorporating the photo-anode. FIG. 18 depicts a control cell which is identical to that in FIG. 17, except that the Nafion layer does not contain the cubane catalyst 1.

It is proposed that light excitation of [Ru(bipy)₂(bipy(COO⁻)₂)] facilitates the injection of an electron from the dye into the conduction band of the TiO₂ generating the observed potential within the cell. With light excitation, 1⁺ is able to catalyse the oxidation of water generating O₂ and H⁺, and resulting in the reduction of 1⁺. The oxidizing potential of [Ru(bipy)₂(bipy(COO⁻)₂)]⁺ is more positive than the oxidation potential of 1 so that it is able to regenerate 1⁺ after water oxidation has taken place. This regenerates the dye, facilitating absorption of another photon and injection of another electron into TiO₂. This photo-anode relay is analogous to the light driven oxidation of water in Photo-system II as depicted in FIG. 11. The potential generated within the TiO₂ drives the reduction of protons at the Pt electrode generating H₂. Thus water is consumed in the process, providing the electrons at the photo-anode, and the protons at the counter electrode.

### Example 12

### Photo-current Testing of the Photo-electrochemical Cell Assembly Prepared in Example 10

The photocurrent of the complete photo-anode and the various intermediates in the construction process were tested by immersing the photo-anode in aqueous 0.1 M Na₂SO₄ with a Pt mesh counter electrode to complete the photo-electrochemical cell. Current was measured using either an Epsilon BAS potentiostat using a two electrode configuration with 0 V between the two electrodes or a standard multimeter. Cells were exposed to 100 mW cm⁻¹ light from a Rofin Polilight 6, over the full spectrum of the Xenon lamp (260 nm->700 nm) and light filtered through a Schott cut-off filter that removed light of wavelength less than 455 nm.

FIG. 19 depicts the current obtained upon illumination of an electrochemical cell of the above type containing only TiO₂ as the photo-anode. The cell generated significant current when exposed to white light, but no current when exposed to light of wavelengths greater than 455 nm. The steady state current generated by such a cell was about 18 μA.

The sensitizer dye [Ru(bipy)₂(bipy(COO⁻)₂)] is highly soluble in water, so when deposited on TiO₂, the dye rapidly desorbs when immersed in water unless it is coated in Nafion. Photo-anodes of TiO₂ sensitized with dye and then coated in a layer of Nafion generate significant current under white light. The steady-state current under white light is about 32 μA. When excited by light of wavelengths greater than 455 nm, there is a transient photocurrent that rapidly decays on the second-timescale towards the observed dark current (FIG. 20). This system demonstrates a sensitized TiO₂ system that can operate in aqueous solvents which could function as a photo-voltaic cell when coupled with an aqueous redox couple.

Photo-anodes constructed of TiO₂ sensitized with dye and then coated with Nafion doped with 1⁺ according to the depiction in FIG. 16, generated significant photocurrent when exposed to both white light and light of wavelength greater than 455 nm (FIGS. 21 and 22). The steady-state current under white light was around 80 μA. Using visible light only (of wavelength greater than 455 nm), a steady-state current of approximately 40 μA was obtained. This is greater than any of the steady state currents obtained from the cells tested and represented by FIGS. 17 and 18.

The photo-current was also observed for equivalent cells where the aqueous 0.1 M Na₂SO₄ was replaced with distilled water. Assuming that water is acting as the electron donor for the observed photo-current, this photo-electrochemical cell is clearly able to oxidise water using only visible light of wavelength greater than 455 nm.

The potential generated between the photo-anode and the Pt counter electrode was measured at 620 mV. As the cell was operated with distilled water as the electrolyte, it indicates that the electrons oxidised from water at the photo-anode reduce protons to H₂ at the Pt counter electrode driven by the 620 mV potential generated at the photo-anode.

### Example 13

### Comparison of the Photo-anode with a Graetzel Cell

A photovoltaic Graetzel cell of identical size and dimensions to the above electrochemical cells was also built and tested for comparative purposes. The cell employed the optimum commercial sensitizing dye N719 in I⁻/I₃⁻ with the standard fabrication arrangement illustrated in FIG. 1. FIG. 23 depicts the comparable response under illumination. As can be seen, the Graetzel cell generated a steady-state current of about 25 μA under illumination.

Thus, it appears that the electrochemical cell in FIG. 16, with current response in FIG. 19, yields a substantially larger current under illumination (40 μA vs. 25 μA; visible light >455 nm only). Moreover, the electrochemical cell clearly splits water, generating hydrogen and oxygen gas. Thus, energy is released in two forms (electrical current and gas production) rather than one. Since the gases created can be separately used to generate an electrical current, the cell appears to display enhanced energy efficiency.

The electrochemical cell containing the preferred embodiment of the present invention consequently appears to offer a highly efficient method of splitting water using solar illumination only.

### Experimental Conditions

Diphenyl phosphinic acid and bis-methoxy-phenyl phosphinic acid were purchased from Lancaster and Aldrich respectively and used without further purification. Tetrabutylammonium hexafluorophosphate (Bu₄NPF₆) was obtained from GFS Chemicals. The supporting electrolyte was dissolved in acetone. Potassium hexa-fluorophosphate was then added to precipitate iodide impurities (as potassium iodide). The solution was filtered and then evaporated to dryness followed by recrystallization from ethanol. The resulting crystalline solid was dissolved in dichloromethane. An insoluble white powder was removed by filtration and the solvent evaporated to dryness to produce electrochemically pure Bu₄NPF₆.

Cyclic voltammograms and controlled potential experiments were conducted using a three electrode system and an inlet and outlet port for degassing solution with nitrogen. A range of working electrodes were used, including a glassy carbon and Pt disc electrodes, FTO coated conductive glass electrodes and a Pt plate electrode. The majority of experiments were conducted using a glassy carbon disk working electrode (diameter 3 mm, area 5.9 mm² (determined from ferrocene in CH₃CN (0.5M Bu₄NPF₆) diffusion coefficient 1.7 10⁻⁵ D/cm²s⁻¹)). All experiments used Pt auxiliary electrodes, either as a Pt wire or a Pt mesh. The reference electrode was Ag/Ag⁺ (0.01 M AgNO₃) in acetonitirile with a double glass frit separating the electrode from the test solution. The ferrocene/ferrocenium (Fc/Fc⁺) oxidation process was used as an internal calibration with all potentials adjusted to vs Fc/Fc⁺ scale. Aqueous experiments were conducted in distilled H₂O (0.1 M Na₂SO₄), degassed with nitrogen and referenced against an Ag/AgCl glass bodied reference electrode with a Vycor frit. All electrochemistry was conducted using a BAS (Bio Analytical Systems) Epsilon CS3 workstation. All experiments were conducted at a 22 (±2)° C. Nafion modified electrodes were prepared by drop casting an aqueous suspension of 10% Nafion onto the working electrode. Doping of the membranes was achieved by immersing them in a 0.5 mM solution of 2⁺ ClO₄⁻. Solid layer electrode coatings were prepared by dropping a solution of 1 or 2 in CH₂Cl₂ onto the surface of a 3 mm diameter glassy carbon electrode and allowing solvent to evaporate.

The light source used for these experiments was white light (312 nm to 700 nm) from a Rofin Australia-Polilight PL6, xenon lamp, used at full intensity with no filters. The total power output of the lamp at the end of the liquid light guide was 7 W. A silicon diode calibrated against a Solar Simulator (1000 W Xe, Oriel) was used to determine that the light intensity was equivalent to one simulated sun (100 mW/cm2 AM1.5) at approximately 5 cm from the tip of the optical cable. The light source used in monochromated experiments was a Neport-Oriel Instruments, Monochromator Model 74000, Arc Lamp-200 W Hg(Xe)OF model 6292, at a single wavelength.

The pH was adjusted using 0.1 M H₂SO₄ and NaOH in H₂O (0.1 M Na₂SO₄) and measured using a Metrohm pH meter. Each pH condition was prepared in individual glass vials. A 3 mm diameter Pt working electrode, Pt wire electrode and reference electrode were fixed together to allow consistent and rapid transition between pH conditions.

The UV/visible absorbance of 2⁺ in CH₃CN, was measured in quartz 0.5 cm cuvettes using a Varian Cary 300 BIO spectrometer. The concentration of the doping solution before and after doping (exposure to Nafion coated working electrode) was determined by reference to a standard curve of the absorbance of solutions of 2⁺ in CH₃CN, of known concentration. Those skilled in the art will appreciate that the invention described herein is susceptible to variations and modifications other than those specifically described. It is to be understood that the invention includes all such variations and modifications which fall within its spirit and scope.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference to any prior art in this specification is not, and should not be taken as, an acknowledgment or any form of suggestion that that prior art forms part of the common general knowledge.

### REFERENCES

1. W. Ruettinger, M. Yagi, K. Wolf, S. Bernasek, G. C. Dismukes, J. Am. Chem. Soc. 122, 10353 (2000).
2. W. F. Ruettinger, D. M. Ho, G. C. Dismukes, Inorg. Chem. 38, 1036 (1999).
3. W. Riittinger, C. Campana, G. C. Dismukes, J. Am. Chem. Soc. 119, 6670 (1997).
4. J.-Z. Wu, E. Sellitto, G. P. A. Yap, J. Sheats, G. C. Dismukes, Inorg. Chem. 43, 5795 (2004).
5. T. G. Carrell, S. Cohen, G. C. Dismukes, J. Mol. Catal. A: Chem. 187, 3 (2002).
6. D. J. Gargas, D. A. Bussian, S. K. Burratto, Nano Letters 5, 2184 (2005).
7. J.-Z. Wu et al., Inorganic Chemistry 45, 189 (2006).

1. A catalyst for the photo-electrolysis of water molecules, the catalyst including:
catalytic groups comprising tetra-manganese-oxo clusters; a conductive support substrate supporting a plurality of the catalytic groups and capable of incorporating water molecules;
wherein, at least some of the catalytic groups supported by the support substrate are able to catalytically interact with water molecules incorporated into the support substrate.

2. The catalyst according to claim 1, wherein the catalytic groups have the formula:
[Mn₄O₄L₆]
where Mn₄O₄ is a manganese-oxo cubane core and L is a ligand stabilising the core.

3. The catalyst according to claim 1, wherein the support substrate has hydrophobic regions and hydrophilic regions.

4. The catalyst according to claim 3, wherein at least some of the catalytic groups are supported in the hydrophobic regions of the support substrate and the water molecules are capable of being incorporated in the hydrophilic regions of the substrate; and
at least some of the catalytic groups supported in the hydrophobic regions are able to catalytically interact with water molecules in the hydrophilic regions.

5. The catalyst according to claim 2, wherein L is a photo-dissociable ligand bound to the core and the catalytic groups are groups having a tendency to destabilise in aqueous solution; and
wherein, upon photo-dissociation of one ligand from a catalytic group, the support substrate stabilises the binding of the other ligands in the same catalytic group, thereby reducing the tendency of the catalytic group to destabilise in the presence of the water molecules compared to the same tendency to destabilise in aqueous solution.

6. The catalyst according to claim 3, wherein the hydrophobic regions are formed by a hydrophobic polymer backbone.

7. The catalyst according to claim 3, wherein the hydrophilic regions are regions of unusable functional groups.

8. The catalyst according to claim 7, wherein L is a photo-dissociable ligand and upon photo-dissociation of a ligand from a catalytic group intermediate catalytic groups are formed, the said ionisable functional groups of the support substrate selected to at least partially stabilise at least one of said intermediate catalytic groups.

9. The catalyst according to claim 8, wherein the intermediate catalytic groups includes a positively charged manganese atom, said ionisable functional groups being selected to form negatively charged functional groups capable of stabilising said positively charged manganese atom.

10. The catalyst according to claim 8, wherein, the intermediate catalytic group includes a negatively charged photo-dissociated ligand, said ionisable functional groups being selected to be groups that are capable of donating a proton to stabilise said negatively charged photo-dissociated ligand.

11. The catalyst according to claim 7, wherein the ionisable functional groups are sulphonate groups.

12. The catalyst according to claim 1, wherein the support substrate is a sulphonated fluoro polymer.

13. The catalyst according to claim 2, wherein the ligands are phosphinate molecules.

14. The catalyst according to claim 2 capable of catalysing water according to the cycle:
[Mn₄O₄(L)₆]⁺̂O₂+L″+[Mn₄O₂(L)₅J²⁺
(ii) [Mn₄O₂Ls]²⁺+L″+2H₂O (4H⁺+4 e″)->[Mn₄O₄L₆J⁺
wherein the catalyst is operable over at least 1,000 cycles

15. The catalyst according to claim 14, wherein the catalyst is operable over at least 100,000 cycles.

16. The catalyst according to claim 1, further including a chemical relay system capable of electrochemically oxidizing the catalytic groups thereby assisting in the regeneration of the catalytic groups.

17. The catalyst according to claim 16 wherein the chemical relay is a photo-electrochemical relay system in the form of a photo-active dye.

18. The catalyst according to claim 17 wherein the photo-active dye is a ruthenium polypyridyl dye.

19. A photo-anode for the electrolysis of water comprising:
an electrode substrate; and
a catalyst for the photo-electrolysis of water molecules, the catalyst including:
catalytic groups comprising tetra-manganese-oxo clusters; and
a conductive support substrate supporting a plurality of the catalytic groups and capable of incorporating water molecules;
wherein, at least some of the catalytic groups supported by the support substrate are able to catalytically interact with water molecules incorporated into the support substrate.

20. A photo-anode according to claim 19, wherein there are multiple layers intermediate the electrode substrate and the catalyst, the layers comprising:
a semiconductor; and a photo-electrochemical relay system contacting the semi-conductor and capable of electrochemically oxidizing the catalytic groups thereby assisting in the regeneration of the catalytic groups.

21. A photo-electrochemical cell for the electrolysis of water comprising:
a chamber capable of containing an aqueous electrolyte;
a cathode in contact with the aqueous electrolyte when the chamber contains the aqueous electrolyte;
a photo-anode including:
an electrode substrate; and
a catalyst for the photo-electrolysis of water molecules, the catalyst including:
catalytic groups comprising tetra-manganese-oxo clusters; a conductive support substrate supporting a plurality of the catalytic groups and capable of incorporating water molecules;
wherein, at least some of the catalytic groups supported by the support substrate are able to catalytically interact with water molecules incorporated into the support substrate,
the photo-anode capable of being electrically connected to said anode in contact with the aqueous electrolyte when the chamber contains the aqueous electrolyte.

22. A photo-electrochemical cell according to claim 21 wherein the chamber contains an aqueous electrolyte.

23. A method of generating hydrogen and oxygen by photo-electrolysing water, the method comprising the steps of:
exposing to light radiation a photo-electrochemical cell including a chamber capable of containing an aqueous electrolyte, a cathode in contact with the aqueous electrolyte when the chamber contains the aqueous electrolyte, and a photo-anode capable of being electrically connected to said anode in contact with said aqueous electrolyte when the chamber contains the aqueous electrolyte; and
applying an electric potential to the cell;
wherein the cell produces hydrogen and oxygen gases.

24. A method of generating electricity by photo-electrolysing water, the method comprising the steps of:
exposing to light radiation a photo-electrochemical cell including a chamber capable of containing an aqueous electrolyte, a cathode in contact with the aqueous electrolyte when the chamber contains the aqueous electrolyte, a photo-anode capable of being electrically connected to said anode in contact with said aqueous electrolyte when the chamber contains the aqueous electrolyte, a semiconductor, and a photo-electrochemical relay system contacting the semi-conductor and capable of electrochemically oxidizing the catalytic groups thereby assisting in the regeneration of the catalytic groups.

25. The method of claim 24, wherein the cell produces hydrogen and oxygen gases and the method further comprises the step of:
passing the hydrogen and oxygen gases produced from the cell to a fuel cell.

26. A method for preparing a photo-electrochemical cell for use in the photo-electrolysis of water, the method including the steps of:
(i) providing a conductive support substrate capable of incorporating water molecules;
(ii) allowing catalytic groups comprising tetra-manganese-oxo clusters to self-assemble on the support substrate so that at least some of the catalytic groups are able to catalytically interact with the water molecules;
(iii) coating the support substrate having the catalytic groups assembled therein with onto an electrode substrate to provide a photo-anode;
(iv) providing a cathode and forming an electrical connection between the photo-anode and the cathode;
(v) providing an aqueous electrolyte between the photo-anode and the cathode to provide a photo-electrochemical cell.

27. A method for preparing a photo-electrochemical cell for the catalysis of water, the method including the steps of
(i) providing a semiconductor layer;
(ii) coating a layer comprising a photo-electrochemical relay system onto the semi-conductor layer;
(iii) coating a layer of a conductive support substrate capable of incorporating water molecules onto the semi-conductor layer having the photo-electrochemical relay system thereon;
(iv) allowing catalytic groups comprising tetra-manganese-oxo clusters to self-assemble on the support substrate so that at least some of the catalytic groups are able to catalytically interact with the water molecules thereby forming a photo-anode; (v) providing an cathode and forming an electrical connection between the photo-anode and the cathode;
(vi) providing an aqueous electrolyte between the photo-anode and the cathode to provide a photo-electrochemical cell.

28. The method according to claim 26 wherein the tetra-manganese-oxo catalytic groups that self-assemble have the formula: [Mn₄O₄L₆] where Mn₄O₄ is a manganese-oxo cubane core and L is a ligand stabilising the core and the groups self-assemble in the support substrate from species that form the catalytic groups.

29. The method according to claim 28 wherein the step of allowing the tetra-manganese-oxo groups to self assemble includes contacting the support substrate with a solution containing the oxidised form of [Mn₄O₄L₆] to cause at least some of the catalytic groups to assemble on the support substrate.

30. The method according to claim 28, wherein the method further includes the step of adding species that form the catalytic groups in situ to the aqueous electrolyte.

31. (canceled)

32. (canceled)

33. The catalyst according to claim 5, wherein the hydrophobic regions are formed by a hydrophobic polymer backbone.

34. The method according to claim 27 wherein the tetra-manganese-oxo catalytic groups that self-assemble have the formula: [Mn₄O₄L₆] where Mn₄O₄ is a manganese-oxo cubane core and L is a ligand stabilising the core and the groups self-assemble in the support substrate from species that form the catalytic groups.

35. The photo-electrochemical cell of claim 21, wherein the cell comprises titanium dioxide and a dye.
